(19) United States
(12) Patent Application Publication
(10) Pub. No.: US 2026/0293277 A1
(43) Pub. Date: Sep. 24, 2026

(54) EPI CUT AND S/D DIELECTRIC WALL FOR N-P SCALING AND EFFECTIVE CAPACITANCE REDUCTION

(71) Applicant: Applied Materials, Inc., Santa Clara, CA (US)

(72) Inventors: Prasad BHOSALE, San Jose, CA (US); John SPORRE, Fremont, CA (US); Sivanandha Krishnan KANAKASABAPATHY, Pleasanton, CA (US); Veeraraghavan S. BASKER, Schenectady, NY (US); Benjamin COLOMBEAU, Salem, MA (US); Balasubramanian PRANATHARTHIHARAN, Santa Clara, CA (US)

(21) Appl. No.: 19/088,633

(22) Filed: Mar. 24, 2025

(51) Int. Cl. H10D 84/01; H10D 84/85

(52) U.S. Cl. CPC H10D 84/0188; H10D 84/017; H10D 84/851

(57) ABSTRACT

The present disclosure provides a method for forming source/drain (S/D) epitaxial regions over gate structures such that the S/D epitaxial regions merge, depositing a hardmask layer over the S/D epitaxial regions, etching the hardmask layer to create openings that laterally trim the S/D epitaxial regions, and depositing a dielectric material over the trimmed S/D epitaxial regions. The dielectric material may be a contact etch stop layer (CESL) that completely encapsulates the trimmed S/D epitaxial regions and that physically separates the trimmed S/D epitaxial regions from each other. The CESL may also assume a shape of the trimmed S/D epitaxial regions.

### BACKGROUND

### Field

Embodiments of the present invention generally relate to semiconductors, and, more particularly, to performing epi volume reduction using epi cuts and source/drain (S/D) dielectric walls.

### Description of the Related Art

In semiconductor devices, epitaxial (epi) layers help form high-performance transistors. As technology advances, the adoption of nanostack architectures has become prevalent to achieve higher device densities and improved electrical characteristics. Nanostacks include alternating layers of epitaxial materials with tailored properties, enabling enhanced carrier mobility and reduced leakage currents. However, as the number of nanostacks increases to meet performance demands, the overall volume of the epitaxial material also grows. This increase in epi volume directly impacts the device's effective capacitance (Ceff), as larger volumes of epitaxial material contribute to higher parasitic capacitances. As such, the increased Ceff results in greater power consumption during device operation.

The increase in power consumption due to larger epi volumes is concerning in applications involving high-speed and low-power operation. With greater parasitic capacitance, the charging and discharging of nodes within the transistor demand more energy, leading to increased heat generation and reduced battery life. Additionally, the expanded epi volume may affect thermal dissipation characteristics, further complicating power management operations. Addressing these challenges demands innovative approaches to balance the benefits of nanostack architectures with the need to minimize Ceff and associated power consumption.

### SUMMARY

In one example, a method includes forming source/drain (S/D) epitaxial regions over gate structures such that the S/D epitaxial regions merge, depositing a hardmask layer over the S/D epitaxial regions, etching the hardmask layer to create openings that laterally trim the S/D epitaxial regions, and depositing a dielectric material over the trimmed S/D epitaxial regions.

In one example, a method includes forming source/drain (S/D) epitaxial regions over gate structures such that the S/D epitaxial regions merge, depositing a hardmask layer over the S/D epitaxial regions, etching the hardmask layer to create openings that laterally trim the S/D epitaxial regions, and depositing dielectric within the openings to define dielectric walls between the trimmed the S/D epitaxial regions.

In one example, a semiconductor structure includes trimmed source/drain (S/D) epitaxial regions disposed over gate structures and a dielectric material adjacent the trimmed S/D epitaxial regions. The dielectric material encapsulates the trimmed S/D epitaxial regions. The dielectric material assumes a shape of the trimmed S/D epitaxial regions. The dielectric material is configured to define dielectric walls between the trimmed S/D epitaxial regions. The dielectric walls extend above a top surface of the trimmed the S/D epitaxial regions. The dielectric walls directly contact at least a portion of side surfaces of the trimmed the S/D epitaxial regions.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIGS. 1A-1E depict a first method of an epitaxial (epi) cut process, according to one or more embodiments.

FIGS. 2A-2D depict a second method of an epi cut process, according to one or more embodiments.

FIGS. 3A-3G depict a third method of an epi cut process, according to one or more embodiments.

FIGS. 4A-4D depict a fourth method of an epi cut process, according to one or more embodiments.

FIGS. 4E-4F depict a fifth method of an epi cut process, according to one or more embodiments.

FIGS. 4G-4H depict a sixth method of an epi cut process, according to one or more embodiments.

FIGS. 5A-5D depict a method of a source/drain (S/D) dielectric wall formation process, according to one or more embodiments.

FIG. 6 is a flowchart illustrating using the first method to carry out the epi cut process, according to one or more embodiments.

FIG. 7 is a flowchart illustrating using the second method to carry out the epi cut process, according to one or more embodiments.

FIG. 8 is a flowchart illustrating using the fourth method to carry out the epi cut process, according to one or more embodiments.

FIG. 9 is a flowchart illustrating using a method to form S/D dielectric walls between the trimmed S/D epitaxial regions, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to semiconductors, and, more particularly, to performing epi volume reduction using epi cuts and source/drain (S/D) dielectric walls.

The semiconductor industry continues to push the boundaries of device miniaturization and performance, using innovative architectures like nanostacks to meet increasing demands for speed, efficiency, and integration density. Nanostack structures, which include alternating epitaxial (epi) layers, have become integral to modern transistor designs due to their ability to enhance carrier mobility and reduce leakage currents. However, as the number of nanostacks increases to achieve higher performance, the overall volume of epitaxial material also grows. This increase in epi volume impacts the effective capacitance (Ceff) of the device, leading to higher power consumption. The resulting rise in power dissipation poses challenges for energy-efficient semiconductor designs, particularly in power-sensitive applications.

However, the implications of larger epi volumes extend beyond power consumption. Increased epi volumes necessitate greater N-P spacing to mitigate parasitic effects and ensure proper device operation. This spacing constraint limits the achievable cell density within a given chip area, counteracting the industry's goals of improving integration density. The balance between achieving higher performance with nanostack architectures and maintaining compact, power-efficient designs is a main focus in ongoing semiconductor research and development.

A major contributor to these challenges is the epitaxial material used for source/drain (S/D) regions, which plays a role in device capacitance and overall performance. The S/D epi is responsible for establishing low-resistance connections while maintaining high drive currents, but it also contributes to the parasitic capacitance of the device, which directly impacts switching speeds and power efficiency, emphasizing the need for optimization of the S/D epi to minimize its impact on device operation.

Moreover, larger epi volumes can complicate the thermal characteristics of the device. Increased material volume not only adds to the parasitic capacitance but also affects heat dissipation, further heightening power and reliability concerns. As power density rises with scaling, effective thermal management becomes an integral part of the design process. Strategies to optimize the epi structure and reduce its contribution to Ceff should also account for the thermal implications to ensure the reliability and longevity of advanced semiconductor devices. As such, reducing the epi volume is beneficial for addressing the challenges posed by larger nanostack architectures, such as increased Ceff, power consumption, and limited cell density.

To address such challenges, the example embodiments present two approaches. One approach to achieve this reduction is the use of epi cuts, which involve removing excess epitaxial material during fabrication. By tailoring the epi layers to the functional requirements of the device, unnecessary material contributing to parasitics can be eliminated, thereby minimizing the overall volume. This technique not only reduces Ceff but also enables tighter control over electrical performance by ensuring that only the essential epitaxial material remains. Another approach involves constraining epi growth through the use of dielectric molds, such as source/drain (S/D) dielectric walls. These molds physically limit the growth of epitaxial material to defined regions, preventing overgrowth and ensuring uniformity. The dielectric mold acts as a boundary that shapes the epi region while simultaneously providing isolation, reducing parasitic capacitance between adjacent components. This method not only optimizes the epi structure for electrical performance but also enhances process scalability by improving consistency across devices, particularly in advanced nodes where variability is a concern.

The benefits of these techniques are substantial. Epi volume reduction directly lowers parasitic capacitance, enabling faster switching speeds and reduced power consumption. Furthermore, by controlling the growth area with dielectric walls, it is possible to achieve tighter N-P spacing and P-P spacing, enhancing cell density. The combined effect of lower capacitance and increased density translates to improved energy efficiency and higher integration levels. Additionally, these methods contribute to better thermal management by reducing the amount of heat-generating material, improving device reliability and extending operational lifespans. By integrating epi cuts and/or dielectric walls, manufacturers can overcome the limitations of traditional nanostack architectures. Stated differently, in the examples, the epi volume is reduced, resulting in an epi-to-gate overlap reduction, which reduces the effective capacitance and the N-P spacing and P-P spacing is reduced, which reduces the cell height. Epi cuts and dielectric walls allow for smaller N-P and P-P spacings, enabling more transistors to fit within a given area. This leads to higher device density. By controlling the lateral growth of epitaxial material, epi cuts and dielectric walls help mitigate short-channel effects, minimize parasitic capacitance, and reduce leakage currents. Epi cuts and dielectric walls offer fine-tuned control over the epitaxial growth process, enabling precise management of the shape and extent of the epi layers, which results in improved process yield and the ability to fabricate more reliable and robust devices.

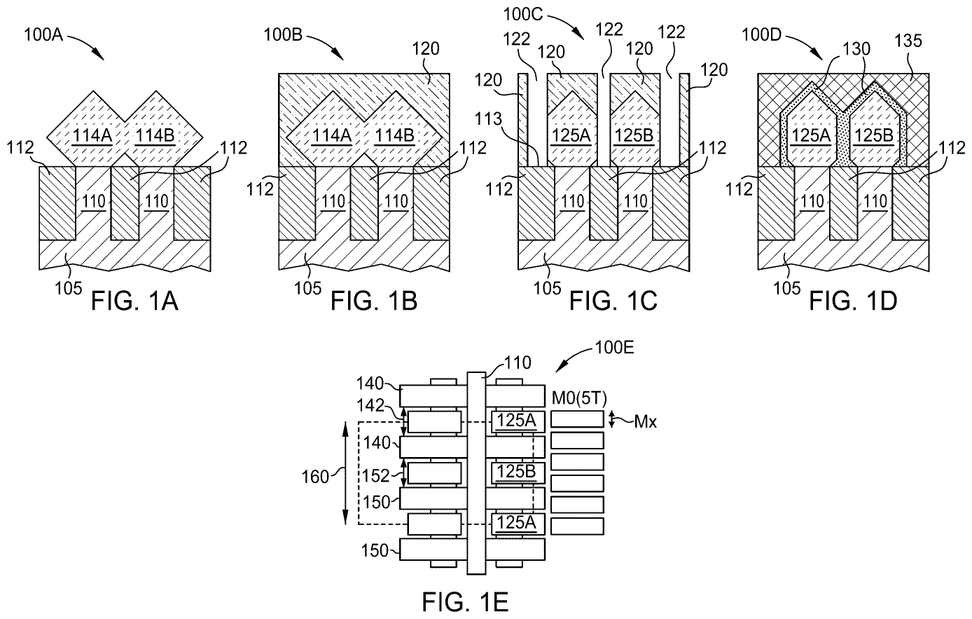

FIGS. 1A-1E depict a first method of an epitaxial (epi) cut process, according to one or more embodiments.

In FIG. 1A, structure 100A shows gate structures 110 formed over a substrate 105. The gate structures 110 may be referred to as gate regions or dummy gates or dummy gate structures or sacrificial structures. The gate structures 100 may be formed adjacent nanosheets stacks. In one example, the gate structures 100 may include an amorphous silicon (a-Si) or a polysilicon. Spacers 112 are formed adjacent to or on a sidewall of the gate structures 110. The spacers 112 may be referred to as gate spacers. The spacers 112 may be composed of a dielectric spacer material including, but not limited to, silicon dioxide (SiO₂), silicon nitride (SiN), silicon boron carbonitride (SiBCN), silicon oxycarbonitride (SiOCN) or silicon oxycarbide (SiOC). The spacers 112 can be formed utilizing a deposition process including, for example, chemical vapor deposition (CVD), plasma enhanced chemical vapor deposition (PECVD) or atomic layer deposition (ALD).

Epitaxial regions or materials or source/drain (S/D) epitaxial regions or growths are formed over the gate structures 110. In one example, a first epitaxial region 114A is formed over and in direct contact with a first gate structure and a second epitaxial region 114B is formed over and in direct contact with a second gate structure. The first epitaxial region 114A and the second epitaxial region 114B are merged. “Merge” refers to the process where the epitaxial grown source and drain regions of neighboring transistors physically and/or electrically merge together. In other words, the first epitaxial region 114A and the second epitaxial region 114B contact each other. The first epitaxial region 114A and the second epitaxial region 114B may be referred to as the epi volume. Epi volume refers to the physical volume of the epitaxial layer that is grown on the S/D regions of a transistor during the fabrication process. This layer, often made of silicon (Si), silicon germanium (SiGe), or silicon-phosphorus (SiP), is deposited through epitaxial growth to improve the electrical and mechanical properties of the S/D regions. The epi volume is thus the total three-dimensional space occupied by the epitaxially grown material. The epi volume includes the vertical and lateral growth over and beyond the original S/D region boundaries.

The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C.

The term “nanosheet,” as used herein, refers to a sheet or a layer having nanoscale dimensions. Further, the term “nanosheets” is meant to encompass other nanoscale structures such as nanowires. For instance, “nanosheet” can refer to a nanowire with a larger width, and/or “nanowire” can refer to a nanosheet with a smaller width, and vice versa.

In some embodiments, the device may be a stacked nanosheet complementary field effect transistor (CFET) device having a gate-all-around (GAA) structure. A GAA structure refers to an architecture where the gate electrode completely surrounds the channel. The GAA structure is a 3D structure with the channel surrounded by the gate on all four sides. The examples herein may apply to GAA structures.

According to an exemplary embodiment, substrate 105 may be a bulk semiconductor wafer, such as a bulk silicon (Si), bulk germanium (Ge), bulk silicon germanium (SiGe) and/or bulk III-V semiconductor wafer. Alternatively, the substrate 105 can be a semiconductor-on-insulator (SOI) wafer. A SOI wafer includes a SOI layer separated from an underlying substrate by a buried insulator. When the buried insulator is an oxide it is referred to herein as a buried oxide or BOX. The SOI layer can include any suitable semiconductor, such as Si, Ge, SiGe, and/or a III-V semiconductor. The substrate 105 may already have pre-built structures (not shown) such as transistors, diodes, capacitors, resistors, interconnects, wiring, etc.

In FIG. 1B, structure 100B shows a spin-on-carbon (SOC) fill 120 taking place. The SOC fill 120 refers to a temporary planarization or hardmask layer. The SOC fill 120 helps isolate the S/D regions from neighboring devices, reducing leakage and parasitic interactions. The SOC fill 120 is a carbon-based dielectric material applied using a spin coating process. The SOC fill 120 is used as a sacrificial layer in patterning and etching steps. The SOC fill 120 provides high-etch selectivity against underlying materials, improving process control in advanced nodes (e.g., 5 nm, 3 nm, and beyond).

In FIG. 1C, structure 100C shows an EPI cut process where openings 122 are formed. The openings 122 extend to a top surface 113 of the spacers 112. The EPI cut is achieved using etching techniques such as wet or dry etching. These processes involve applying chemical or plasma-based methods to selectively remove material. The EPI cut trims the edges or outer regions of the first epitaxial region 114A and the second epitaxial region 114B. This results in trimmed epi region 125A and trimmed epi region 125B. As such, the EPI cut is used to manage epitaxial growth for S/D regions, where excessive material can lead to higher capacitance and degraded performance. The EPI cut can define precise geometries in 3D structures like GAA transistors. The benefits of the EPI cut include at least reducing parasitic capacitance, better control of device characteristics, and enhanced cell density. Trimming excess epi material lowers the Ceff, improving switching speeds and reducing power consumption. Precise shaping of the epi regions enables consistent electrical properties across the device. By optimizing the volume and placement of epi material, epi cuts can help reduce N-P spacing, increasing the density of transistors on a chip.

As such, epi cuts are used to modify the epi layer growth in the S/D regions of transistors. The purpose of epi cuts is to reduce the lateral extent or lateral dimensions or lateral regions of the epi layer, which in turn helps optimize the N-P spacing and P-P spacing between adjacent transistor elements. This approach is useful in advanced technology nodes, where device scaling and tight transistor packing are used for achieving high performance and minimizing power consumption. By controlling the epi growth, epi cuts help improve both device density and the electrical performance of the transistors.

In FIG. 1D, structure 100D shows the removal of the remaining SOC fill, the deposition of a contact etch stop layer (CESL) 130, and the deposition of an interlayer dielectric (ILD) 135. The CESL 130 completely surrounds or encapsulates the trimmed epi region 125A and the trimmed epi region 125B. The CESL 130 may assume the shape of the trimmed epi region 125A and the trimmed epi region 125B. The CESL 130 physically and/or electrically separates the trimmed epi region 125A from the trimmed epi region 125B. The ILD 135 surrounds and directly contacts the CESL 130. The ILD 135 may also be referred to as a middle-of-line (MOL) ILD.

The CESL 130 is usually made from silicon nitride (Si₃N₄) or other robust dielectric materials with high etch selectivity to silicon and other oxides.

Suitable dielectric materials for forming the ILD 135 include but are not limited to, silicon oxide (SiO), silicon nitride (SiN), silicon oxynitride (SiON), silicon oxycarbide (SiCO), silicon carbide oxynitride (SiCON), or any suitable combination of such materials.

In FIG. 1E, a top-down view 100E shows the gate structure 110 formed over a nanosheet stack. The nanosheet stack in a GAA structure includes n-type metal oxide semiconductor (NMOS) sheets and p-type metal oxide semiconductor (PMOS) sheets. In the example, PMOS sheets 140 and NMOS sheets 150 are shown formed under the gate structure 110. The PMOS sheets and NMOS sheets may be referred to as layers or transistors. The trimmed epi region 125A and the trimmed epi region 125B separate the PMOS sheets 140 and the NMOS sheets 150. The NMOS sheets 150 are usually constructed from Si and the PMOS sheets 140 are usually constructed from SiGe. The epi cut defines the P-P spacing 142 and the N-P spacing 152. The cell height 160 is defined from a center point of a PMOS epi cut to a center point of an NMOS epi cut.

N-P spacing refers to the distance between the n-type and p-type regions of a transistor, specifically between the source (n-type) and drain (p-type) or vice versa. In complementary metal oxide semiconductor (CMOS) designs, these regions are formed in the bulk semiconductor substrate (e.g., Si), and the spacing between them is critical to the device's electrical characteristics, including leakage current and short-channel effects. The N-P spacing affects how well the transistor performs in terms of current drive capability, leakage currents, and overall device stability.

P-P spacing refers to the distance between two adjacent p-type regions in a CMOS structure. These regions may belong to two different transistors or portions of a single transistor. This spacing is also critical for minimizing cross-talk between neighboring transistors, which could otherwise result in unwanted capacitance or signal interference. Like N-P spacing, tight control over P-P spacing is useful for managing leakage currents, preventing parasitic effects, and improving overall device performance. Reducing the P-P spacing also allows for higher transistor density, which helps improve chip performance and minimizing size.

Epi cuts can help reduce the lateral dimensions of this epi material, particularly in regions where source and drain are tightly spaced. This is beneficial in devices with small channel lengths, where tight N-P spacing may otherwise lead to unwanted short-channel effects. By introducing cuts in the epi material or selectively removing excess epi growth, the N-P spacing can be reduced while maintaining electrical isolation between the source and drain regions. This enables scaling down the device size without compromising performance or reliability. Epi cuts can also be used to control the growth of epitaxial material in regions where p-type regions are adjacent. By limiting the epi material in these regions, P-P spacing can be reduced, which is beneficial for minimizing parasitic capacitance between adjacent transistors and improving overall signal integrity. Additionally, tighter P-P spacing enables higher transistor density, which is beneficial for increasing the performance of integrated circuits and reducing chip size.

Therefore, in the examples, the epi volume is reduced resulting in an epi-to-gate overlap reduction, which reduces the effective capacitance and the N-P spacing and P-P spacing is reduced, which reduces the cell height.

One benefit of reducing the epi volume is the reduction of epi-to-gate overlap. In traditional designs, the epitaxially grown S/D regions extend under the gate, creating overlap capacitance between the gate and the S/D. While some overlap is necessary to ensure proper current injection and reduce resistance, excessive overlap increases the effective parasitic capacitance. High capacitance results in increased power consumption due to higher dynamic switching power and reduced switching speed since the capacitance directly impacts the RC delay. By reducing the epi volume, the overlap with the gate is minimized, leading to a decrease in this parasitic capacitance. This enhances switching performance and reduces energy losses.

Another benefit of reducing the epi volume is shrinking the spacing between NMOS and PMOS transistors in CMOS designs. Traditionally, a larger S/D region needs greater spacing to prevent electrical interference and ensure adequate isolation between transistors. With smaller epi regions, the spacing can be reduced without compromising isolation or electrical performance. This results in cell height reduction and improved area efficiency. The total vertical dimension of standard cells in a chip layout is reduced, enabling denser integration of logic gates. This is beneficial in meeting the scaling requirements of advanced technology nodes (e.g., 3 nm and below). Reduced cell height allows for higher transistor density, leading to smaller die sizes and potentially lower manufacturing costs. In CMOS designs, spacing between adjacent NMOS-PMOS pairs (N-P) and between PMOS transistors (P-P) within a cell is critical for ensuring electrical performance and reliability. Reducing these spacings directly impacts coupling capacitance reduction and provides for shorter signal paths. Smaller spacing with optimized epi regions lowers the coupling capacitance between adjacent transistors. This reduces signal interference, enhancing circuit robustness. With reduced spacing, signals propagate more quickly through the circuit, improving overall timing and reducing power consumption.

Therefore, by minimizing epi-to-gate overlap, effective capacitance is reduced, improving switching performance and power efficiency. Simultaneously, tighter N-P and P-P spacing reduces cell height, leading to increased transistor density and better area utilization.

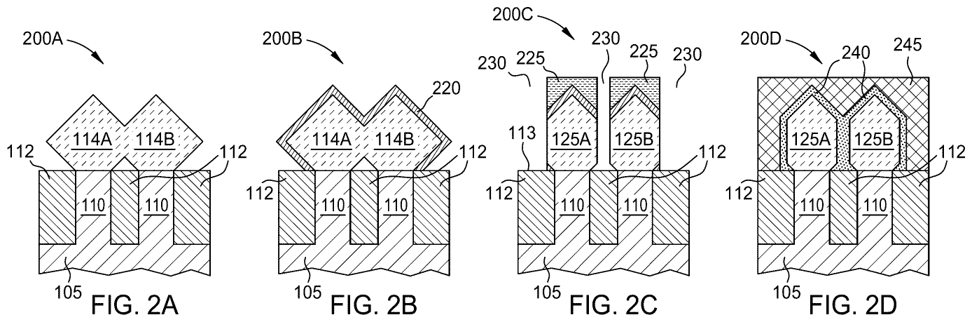

FIGS. 2A-2D depict a second method of an epi cut process, according to one or more embodiments.

In FIG. 2A, structure 200A shows the gate structures 110 formed over the substrate 105. The gate structures 100 may be formed adjacent nanosheets stacks. Spacers 112 are formed adjacent to or on a sidewall of the gate structures 110. The spacers 112 may be referred to as gate spacers. Epitaxial regions or materials or S/D epitaxial regions or growths are formed over the gate structures 110. In one example, a first epitaxial region 114A is formed over and in direct contact with a first gate structure and a second epitaxial region 114B is formed over and in direct contact with a second gate structure. The first epitaxial region 114A and the second epitaxial region 114B are merged.

In FIG. 2B, structure 200B shows a sacrificial layer 220 formed over the first epitaxial region 114A and the second epitaxial region 114B. The sacrificial layer 220 may assume the shape of the first epitaxial region 114A and the second epitaxial region 114B. In one example, the sacrificial layer 220 may be titanium nitride (TiN) or aluminum oxide (AlOx).

In FIG. 2C, structure 200C shows performing an SOC fill 225 and then etching openings 230 to a top surface 113 of the spacers 112. This is an EPI cut process where the openings 122 are formed. The EPI cut is achieved using etching techniques such as wet or dry etching. These processes involve applying chemical or plasma-based methods to selectively remove material. The EPI cut trims the edges or outer regions of the first epitaxial region 114A and the second epitaxial region 114B. This results in trimmed epi region 125A and trimmed epi region 125B.

The benefits of the EPI cut include at least reducing parasitic capacitance, better control of device characteristics, and enhanced cell density. Trimming excess epi material lowers the Ceff, improving switching speeds and reducing power consumption. Precise shaping of the epi regions enables consistent electrical properties across the device. By optimizing the volume and placement of epi material, epi cuts can help reduce N-P spacing, increasing the density of transistors on a chip. As such, epi cuts are used to modify the epi layer growth in the S/D regions of transistors. The purpose of epi cuts is to reduce the lateral extent of the epi layer, which in turn helps optimize the N-P spacing and P-P spacing between adjacent transistor elements.

In FIG. 2D, structure 200D shows the removal of the remaining SOC fill, the removal of the remaining sacrificial material, the deposition of a CESL 240, and the deposition of an ILD 245. The CESL 240 completely surrounds or encapsulates the trimmed epi region 125A and the trimmed epi region 125B. The CESL 240 may assume the shape of the trimmed epi region 125A and the trimmed epi region 125B. The CESL 240 separates the trimmed epi region 125A from the trimmed epi region 125B. The ILD 245 surrounds and directly contacts the CESL 240. The ILD 245 may also be referred to as a MOL ILD.

Therefore, in FIGS. 1A-1D, in a first epi cut method, the SOC fill occurs directly on the S/D epitaxial regions or growths, an epi cut takes place, and dielectric is formed. In contrast, in FIGS. 2A-2D, in a second epi cut method, a sacrificial material is deposited before the SOC fill occurs, an epi cut takes place, and dielectric is formed. The purpose of the sacrificial material may be to protect the underlying gate spacers.

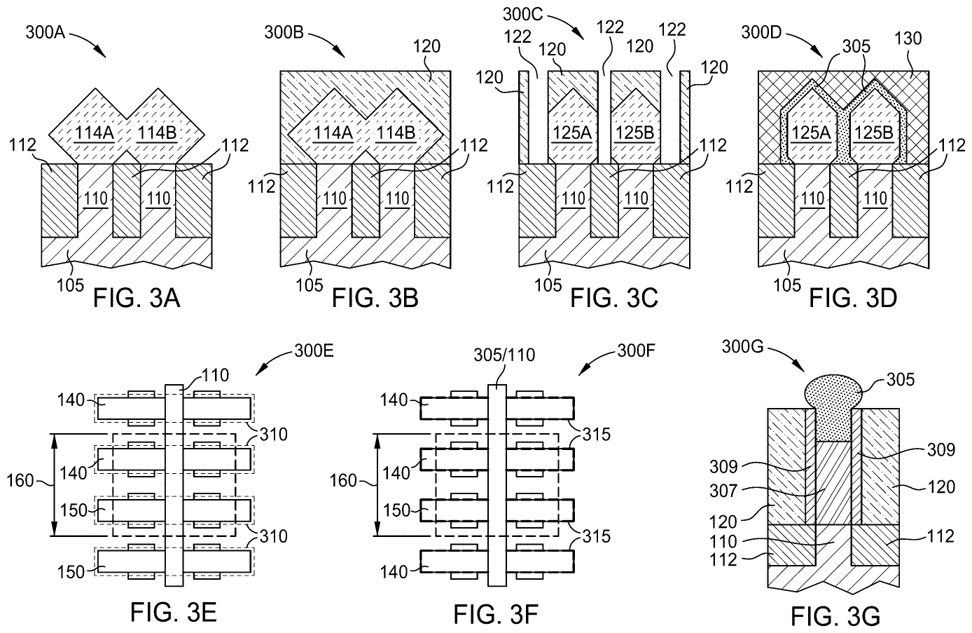

FIGS. 3A-3G depict a third method of an epi cut process, according to one or more embodiments.

FIGS. 3A-3D are similar to FIGS. 1A-1D, except that a “helmet” process is used in FIG. 3D to form the CESL 305. In one example, the “helmet” process is a SiN helmet process, which refers to the deposition of a SiN layer to protect or encapsulate the trimmed epi region 125A and the trimmed epi region 125B. The term “helmet” emphasizes the SiN's role as a protective cap or shield over the trimmed epi region 125A and the trimmed epi region 125B.

In FIG. 3E, a top-down view 300E shows an RX mask 310 formed over the PMOS sheets 140 and the NMOS sheets 150. The RX mask 310 is used during lithography to define the active regions (where the transistors will be formed) on the Si wafer. The “RX” refers to the active region of the cell. These regions correspond to the areas where doping, epitaxial growth or other modifications will take place to create the NMOS and PMOS transistors. The RX mask 310 is deposited over the PMOS and NMOS transistors to increase the litho dose for patterning. The dose refers to the amount of energy delivered to the photoresist during exposure. A higher dose increases the exposure energy. Increasing the litho dose using the RX mask 310 may enhance the contrast of the photoresist pattern to ensure well-defined edges for the active regions.

In FIG. 3F, a top-down view 300F shows the CESL 305 formed with a “helmet” process. The gate structure 110 with the CESL 305 is formed over the nanosheet stack, that is, the NMOS and PMOS sheets or layers or transistors. The SiN layer 315 extends around the NMOS and PMOS sheets.

In FIG. 3G, a cross-sectional view 300G shows the gate structure 110, where a material 307 is formed over and in direct contact with the gate structure 110. The material 307 may be, e.g., polysilicon. The SiN layer 315 is formed over and in direct contact with the material 307. Spacers 309 may be formed adjacent the sidewalls of the material 307 and a bottom portion of the SiN layer 315. The “helmet” section of the SiN layer 315 partially extends over the spacers 309 and the SOC fill 120.

Therefore, in FIGS. 1A-1D, in a first epi cut method, the SOC fill occurs directly on the S/D epitaxial regions or growths, an epi cut takes place, and dielectric is formed. In FIGS. 2A-2D, in a second epi cut method, a sacrificial material is deposited before the SOC fill occurs, an epi cut takes place, and dielectric is formed. The purpose of the sacrificial material may be to protect the underlying gate spacers. In contrast, in FIGS. 3A-3D, in a third epi cut method, a SiN helmet process is employed to create a protective cap or shield at the top of the trimmed epi region 125A and the trimmed epi region 125B. The protective cap or shield is formed over, e.g., a polysilicon material formed over the gate structure 110. The purpose of the protective cap is to safeguard and preserve the gate structure 110. The presence of the protective cap ensures the trimming process selectively targets the S/D epi regions without impacting the gate structure.

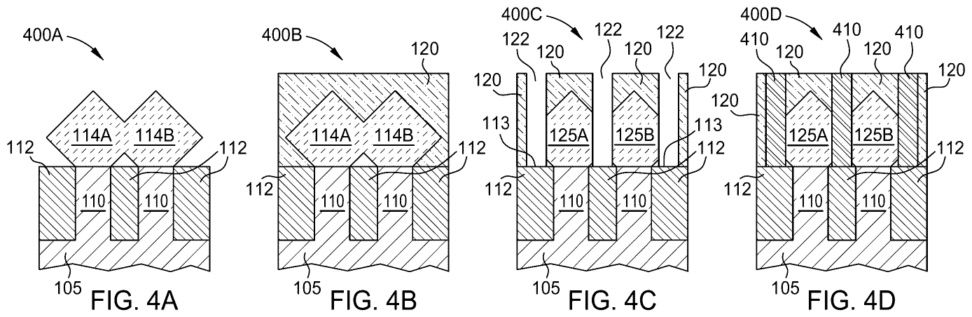

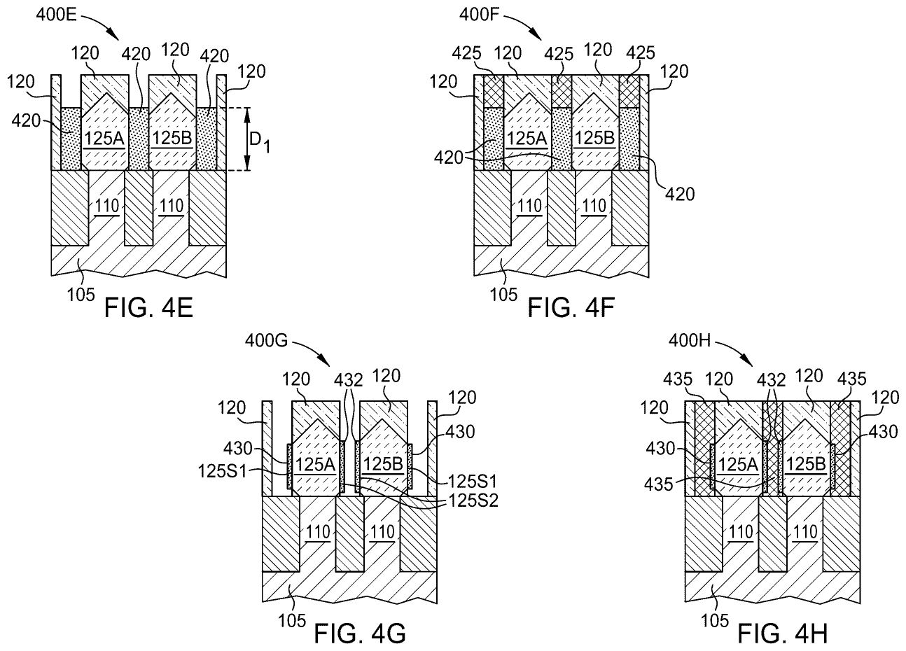

FIGS. 4A-4D depict a fourth method of an epi cut process, according to one or more embodiments.

In FIG. 4A, structure 400A shows the gate structures 110 formed over the substrate 105. The gate structures 100 may be formed adjacent nanosheets stacks. Spacers 112 are formed adjacent to or on a sidewall of the gate structures 110. The spacers 112 may be referred to as gate spacers. Epitaxial regions or materials or S/D epitaxial regions or growths are formed over the gate structures 110. In one example, a first epitaxial region 114A is formed over and in direct contact with a first gate structure and a second epitaxial region 114B is formed over and in direct contact with a second gate structure. The first epitaxial region 114A and the second epitaxial region 114B are merged.

In FIG. 4B, structure 400B shows a SOC fill 120 taking place. The SOC fill 120 refers to a temporary planarization or hardmask layer.

In FIG. 4C, structure 400C shows an EPI cut process where openings 122 are formed. The openings 122 extend to a top surface 113 of the spacers 112. The EPI cut is achieved using etching techniques such as wet or dry etching. The EPI cut trims the edges or outer regions of the first epitaxial region 114A and the second epitaxial region 114B. This results in trimmed epi region 125A and trimmed epi region 125B. As such, the EPI cut is used to manage epitaxial growth for S/D regions. The EPI cut can define precise geometries in 3D structures like GAA transistors. The benefits of the EPI cut include at least reducing parasitic capacitance, better control of device characteristics, and enhanced cell density. Trimming excess epi material lowers Ceff, improving switching speeds and reducing power consumption. Precise shaping of the epi regions enables consistent electrical properties across the device. By optimizing the volume and placement of epi material, epi cuts can help reduce N-P spacing, increasing the density of transistors on a chip.

In FIG. 4D, structure 400D shows a dielectric fill that forms dielectric walls 410 or dielectric pillars. The dielectric walls 410 include an insulating material. A dielectric fill refers to the process of depositing an insulating material into voids, trenches, gaps, or spaces in a semiconductor device to electrically isolate various structures, such as metal interconnects, gates, or active regions. The purpose of dielectric fill is to prevent electrical shorts and interference between different components while maintaining the structural integrity of the device. The purpose of the dielectric fill is to also separate the trimmed epi region 125A from the trimmed epi region 125B. Dielectric fill materials are chosen based on their electrical insulating properties, mechanical stability, and compatibility with the manufacturing process. In the examples, the dielectric walls 410 may be constructed from, e.g., SiO₂, low-k dielectrics, SiN, high-k dielectrics, and polymers.

The dielectric walls 410 extend above a top surface of the trimmed epi region 125A and the trimmed epi region 125B. The dielectric walls 410 directly contact at least a portion of side surfaces of the trimmed epi region 125A and the trimmed epi region 125B. The dielectric walls 410 directly contact a top surface of the gate spacers. The dielectric walls 410 are vertically aligned with the gate spacers. The dielectric walls 410 are vertically offset from the gate structures 110. The trimmed epi region 125A and the trimmed epi region 125B are confined between the dielectric walls 410.

Therefore, in FIGS. 1A-1D, in a first epi cut method, the SOC fill occurs directly on the S/D epitaxial regions or growths, an epi cut takes place, and dielectric is formed. In FIGS. 2A-2D, in a second epi cut method, a sacrificial material is deposited before the SOC fill occurs, an epi cut takes place, and dielectric is formed. The purpose of the sacrificial material may be to protect the underlying gate spacers. In FIGS. 3A-3D, in a third epi cut method, a SiN helmet process is employed to create a protective cap or shield at the top of the trimmed epi region 125A and the trimmed epi region 125B. The protective cap or shield is formed over, e.g., a polysilicon material formed over the gate structure 110. The purpose of the protective cap is to safeguard and preserve the gate structure 110. The presence of the protective cap ensures the trimming process selectively targets the S/D epi regions without impacting the gate structure. In contrast, in FIGS. 4A-4D, in a fourth epi cut method, after the epi cut takes place, a dielectric material is formed in the openings to form dielectric walls or dielectric pillars between the trimmed epi region 125A and the trimmed epi region 125B.

FIGS. 4E-4F depict a fifth method of an epi cut process, according to one or more embodiments.

In FIG. 4C, structure 400C shows an EPI cut process where openings 122 are formed. The openings 122 extend to a top surface 113 of the spacers 112. The EPI cut is achieved using etching techniques such as wet or dry etching. FIG. 4E continues from FIG. 4C. In FIG. 4E, structure 400E shows a dielectric fill that forms dielectric walls 420 or dielectric pillars. The dielectric walls 420 include an insulating material. The purpose of dielectric fill is to prevent electrical shorts and interference between different components while maintaining the structural integrity of the device. The purpose of the dielectric fill is to also separate the trimmed epi region 125A from the trimmed epi region 125B. The dielectric walls 420 do not extend to the top surface of the SOC fill 120 (as in FIG. 4D). Instead, the dielectric walls 420 extend below a top surface of the trimmed epi region 125A and the trimmed epi region 125B. The dielectric walls 420 extend a distance, D1 within the openings 122. The dielectric walls 420 contact an entire side surface of the trimmed epi region 125A and the trimmed epi region 125B. In one example, the dielectric walls 420 extend to a topmost portion of the side walls of the trimmed epi region 125A and the trimmed epi region 125B. In another example, the dielectric walls 420 extend just over a topmost portion of the side walls of the trimmed epi region 125A and the trimmed epi region 125B. This distance is designated by D1.

In FIG. 4F, in structure 400F, a dielectric cap 425 is deposited over the dielectric walls 420. The dielectric cap 425 can be formed from different materials, such as, but not limited to, silicon nitride (Si₃N₄), silicon carbide (SiC), silicon dioxide (SiO₂), and low-k dielectrics. The dielectric cap 425 can be planarized using, e.g., chemical mechanical planarization.

Thus, in FIGS. 4E-4F, in a fifth epi cut method, after the epi cut takes place, a dielectric material is formed in the openings to form dielectric walls or dielectric pillars between the trimmed epi region 125A and the trimmed epi region 125B. The dielectric walls 420 extend below a top surface of the trimmed epi region 125A and the trimmed epi region 125B.

FIGS. 4G-4H depict a sixth method of an epi cut process, according to one or more embodiments.

In FIG. 4C, structure 400C shows an EPI cut process where openings 122 are formed. The openings 122 extend to a top surface 113 of the spacers 112. The EPI cut is achieved using etching techniques such as wet or dry etching. FIG. 4G continues from FIG. 4C. In FIG. 4G, structure 400G shows a dielectric fill that forms dielectric walls 430 and dielectric walls 432 adjacent the sidewalls of the trimmed epi region 125A and the trimmed epi region 125B. The dielectric walls 430 and the dielectric walls 432 can be referred to as dielectric barriers or dielectric layers or dielectric structures or dielectric sections/portions. In one example, the dielectric walls 430 contact side surfaces 125S1 of the trimmed epi region 125A and the trimmed epi region 125B and the dielectric walls 432 contact side surfaces 125S2 of the trimmed epi region 125A and the trimmed epi region 125B. In one example, the side surfaces 125S1 and the side surfaces 125S2 have an equal length. In other examples, the side surfaces 125S1 and the side surfaces 125S2 are unequal in length. As such, the dielectric walls 430 and the dielectric walls 432 can have the same or different lengths. In the example, the dielectric walls 430 are shown to have a different length then the dielectric walls 432, which results in different sizes for the dielectric walls 430 compared to the dielectric walls 432.

The dielectric walls 430 and the dielectric walls 432 do not contact the side surfaces of the SOC fill 120. The dielectric walls 430 and the dielectric walls 432 do not contact the spacers 112. The dielectric walls 430 and the dielectric walls 432 are configured to only contact the side surfaces or side walls of the trimmed epi region 125A and the trimmed epi region 125B. A width of the dielectric walls 430 and the dielectric walls 432 is less than a width defined by the openings 122.

In FIG. 4H, in structure 400H, a dielectric cap or shielding cap or capping dielectric 435 is deposited adjacent the dielectric walls 430 and the dielectric walls 432. The capping dielectric 435 can be formed from different materials, such as, but not limited to, silicon nitride (Si₃N₄), silicon carbide (SiC), silicon dioxide (SiO₂), and low-k dielectrics. The capping dielectric 435 can be planarized using, e.g., chemical mechanical planarization. The capping dielectric 435 contacts three surfaces of the dielectric walls 430 and the dielectric walls 432.

Thus, in FIGS. 4G-4H, in a sixth epi cut method, after the epi cut takes place, a dielectric material is formed in the openings to form dielectric walls adjacent sidewalls of the trimmed epi region 125A and the trimmed epi region 125B. The dielectric walls do not extend to the spacers 112 and do not laterally extend to the SOC fill 120.

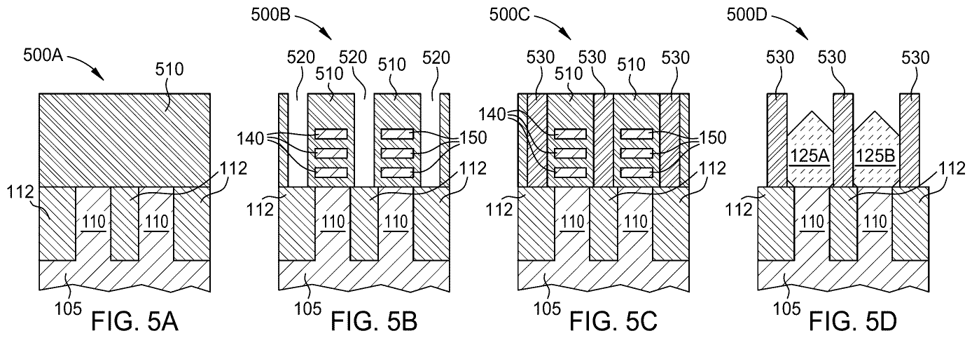

FIGS. 5A-5D depict a method of a source/drain (S/D) dielectric wall formation process, according to one or more embodiments.

In FIG. 5A, structure 500A shows the gate structures 110 formed over the substrate 105. The gate structures 100 may be formed adjacent nanosheets stacks. Spacers 112 are formed adjacent to or on a sidewall of the gate structures 110. The spacers 112 may be referred to as gate spacers. A SOC fill 510 fills the S/D epitaxial regions.

In FIG. 5B, structure 500B shows etching of the SOC fill 510 to form openings 520. The nanosheet stacks are also shown. The nanosheet stacks include NMOS sheets 150 and PMOS sheets 140.

In FIG. 5C, structure 500C shows a dielectric fill that results in dielectric walls 530 formed between the nanosheet stacks. The dielectric walls 530 include an insulating material. A dielectric fill refers to the process of depositing an insulating material into voids, trenches, gaps, or spaces in a semiconductor device to electrically isolate various structures, such as metal interconnects, gates, or active regions. Dielectric fill materials are chosen based on their electrical insulating properties, mechanical stability, and compatibility with the manufacturing process. In the examples, the dielectric walls 530 may be constructed from, e.g., SiO₂, low-k dielectrics, SiN, high-k dielectrics, and polymers. The dielectric walls 530 constrain the epi growth as they act as a dielectric mold.

In FIG. 5D, structure 500D shows the removal of the SOC via, e.g., SOC ash. SOC ashing is used after the SOC has served its purpose as a hardmask or planarization layer. The SOC ash completely removes the carbon layer to expose the trimmed epi region 125A and the trimmed epi region 125B.

The dielectric walls 530 extend above a top surface of the trimmed epi region 125A and the trimmed epi region 125B. The dielectric walls 530 directly contact at least a portion of side surfaces of the trimmed epi region 125A and the trimmed epi region 125B. The dielectric walls 530 directly contact a top surface of the gate spacers. The dielectric walls 530 are vertically aligned with the gate spacers. The dielectric walls 530 are vertically offset from the gate structures 110. The trimmed epi region 125A and the trimmed epi region 125B are confined between the dielectric walls 530.

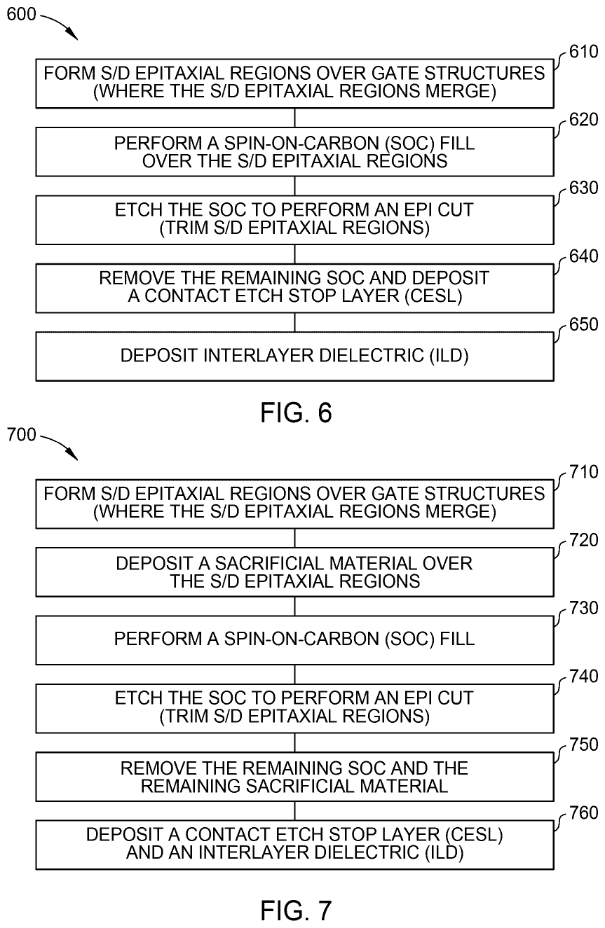

FIG. 6 is a flowchart 600 illustrating using the first method to carry out the epi cut process, according to one or more embodiments.

At 610, S/D epitaxial regions are formed over gate structures where the S/D epitaxial regions merge. A first epitaxial region and a second epitaxial region are merged. “Merge” refers to the process where the epitaxial grown source and drain regions of neighboring transistors physically and/or electrically merge together. In other words, the first epitaxial region directly contacts the second epitaxial region.

At 620, a SOC fill is performed over the S/D epitaxial regions. The SOC fill refers to a temporary planarization or hardmask layer. The SOC fill helps isolate the S/D regions from neighboring devices, reducing leakage and parasitic interactions.

At 630, the SOC is etched to perform an EPI cut, that is, to trim the S/D epitaxial regions. The EPI cut trims the edges or outer regions of the first epitaxial region and the second epitaxial region. This results in a first trimmed epi region and a second trimmed epi region. As such, the EPI cut is used to manage epitaxial growth for S/D regions, where excessive material can lead to higher capacitance and degraded performance.

At 640, the remaining SOC is removed and a CESL is deposited. The CESL completely surrounds or encapsulates the first trimmed epi region and the second trimmed epi region. The CESL may assume the shape of the first trimmed epi region and the second trimmed epi region. The CESL separates the first trimmed epi region from the second trimmed epi region.

At 650, an ILD is deposited. The ILD surrounds and directly contacts the CESL. The ILD may also be referred to as a MOL ILD.

FIG. 7 is a flowchart 700 illustrating using the second method to carry out the epi cut process, according to one or more embodiments.

At 710, S/D epitaxial regions are formed over gate structures where the S/D epitaxial regions merge. A first epitaxial region and a second epitaxial region are merged. “Merge” refers to the process where the epitaxial grown source and drain regions of neighboring transistors physically and/or electrically merge together. In other words, the first epitaxial region directly contacts the second epitaxial region.

At 720, a sacrificial material is deposited over the S/D epitaxial regions. The sacrificial layer may assume the shape of the first epitaxial region and the second epitaxial region. In one example, the sacrificial layer may be TiN or AlOx. The sacrificial layer protects the underlying gate spacers.

At 730, a SOC fill is performed. The SOC fill refers to a temporary planarization or hardmask layer. The SOC fill helps isolate the S/D regions from neighboring devices, reducing leakage and parasitic interactions.

At 740, the SOC is etched to perform an EPI cut, that is, to trim the S/D epitaxial regions. The EPI cut trims the edges or outer regions of the first epitaxial region and the second epitaxial region. This results in a first trimmed epi region and a second trimmed epi region. As such, the EPI cut is used to manage epitaxial growth for S/D regions, where excessive material can lead to higher capacitance and degraded performance.

At 750, the remaining SOC and the remaining sacrificial material are selectively removed. The SOC and the remaining sacrificial material may be removed using plasma etching and wet chemical etch processes.

At 760, a CESL and an ILD are deposited. The CESL completely surrounds or encapsulates the first trimmed epi region and the second trimmed epi region. The CESL may assume the shape of the first trimmed epi region and the second trimmed epi region. The ILD surrounds and directly contacts the CESL.

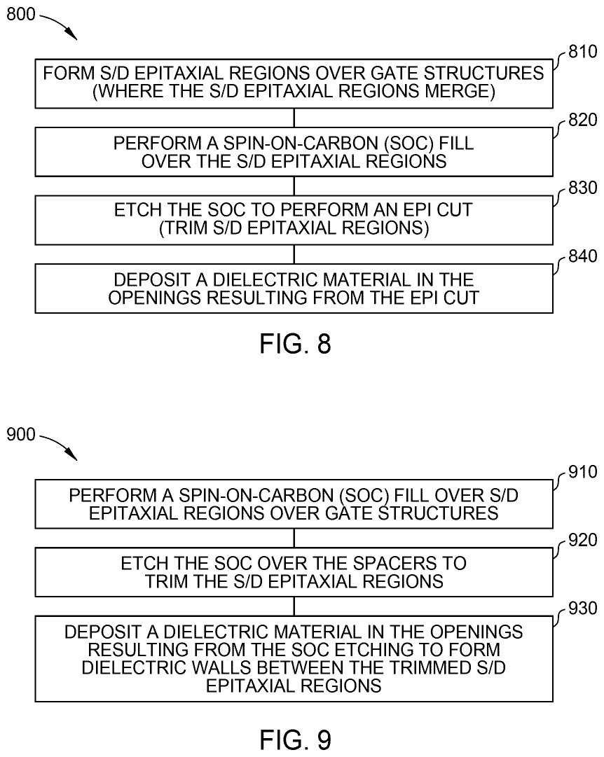

FIG. 8 is a flowchart 800 illustrating using the fourth method to carry out the epi cut process, according to one or more embodiments.

At 810, S/D epitaxial regions are formed over gate structures where the S/D epitaxial regions merge. A first epitaxial region and a second epitaxial region are merged. “Merge” refers to the process where the epitaxial grown source and drain regions of neighboring transistors physically and/or electrically merge together. In other words, the first epitaxial region directly contacts the second epitaxial region.

At 820, a SOC fill is performed over the S/D epitaxial regions. The SOC fill refers to a temporary planarization or hardmask layer. The SOC fill helps isolate the S/D regions from neighboring devices, reducing leakage and parasitic interactions.

At 830, the SOC is etched to perform an EPI cut, that is, to trim the S/D epitaxial regions. The EPI cut trims the edges or outer regions of the first epitaxial region and the second epitaxial region. This results in a first trimmed epi region and a second trimmed epi region. As such, the EPI cut is used to manage epitaxial growth for S/D regions, where excessive material can lead to higher capacitance and degraded performance.

At 840, a dielectric material is deposited in the openings resulting from the EPI cut. The dielectric material forms dielectric walls or dielectric pillars. The dielectric walls physically and/or electrically separate the first trimmed epi region from the second trimmed epi region.

FIG. 9 is a flowchart 900 illustrating using a method to form S/D dielectric walls between the trimmed S/D epitaxial regions, according to one or more embodiments.

At 910, a SOC fill is performed over S/D epitaxial regions over gate structures.

At 920, the SOC over the spacers is etched to trim the S/D epitaxial regions.

At 930, a dielectric material is deposited in the openings resulting from the SOC etching to form dielectric walls between the trimmed S/D epitaxial regions. The SOC is removed using, e.g., ashing.

In conclusion, the example embodiments present two approaches to achieve epi volume reduction. One approach to achieve epi volume reduction is by using epi cuts, which involve removing excess epitaxial material during fabrication. By tailoring the epi layers to the functional requirements of the device, unnecessary material contributing to parasitics can be eliminated, thereby minimizing the overall volume. This technique not only reduces Ceff but also enables tighter control over electrical performance by ensuring that only the essential epitaxial material remains. Another approach to achieve epi volume reduction involves constraining epi growth through the use of dielectric molds, such as S/D dielectric walls. These molds or walls physically limit the growth of epitaxial material to defined regions, preventing overgrowth and ensuring uniformity. The dielectric mold acts as a boundary that shapes the epi region while simultaneously providing isolation, reducing parasitic capacitance between adjacent components. This method not only optimizes the epi structure for electrical performance but also enhances process scalability by improving consistency across devices.

Stated differently, in the examples, the epi volume is reduced, resulting in an epi-to-gate overlap reduction, which reduces the effective capacitance and the N-P spacing and P-P spacing is reduced, which reduces the cell height. Epi cuts and dielectric walls allow for smaller N-P and P-P spacings, enabling more transistors to fit within a given area. This leads to higher device density. By controlling the lateral growth of epitaxial material, epi cuts and dielectric walls help mitigate short-channel effects, minimize parasitic capacitance, and reduce leakage currents. Epi cuts and dielectric walls offer fine-tuned control over the epitaxial growth process, enabling precise management of the shape and extent of the epi layers, which results in improved process yield and the ability to fabricate more reliable and robust devices.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112(f), for any limitations of any of the claims, except for those in which the claim expressly uses the words ‘means for’ together with an associated function.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
forming source/drain (S/D) epitaxial regions over gate structures such that the S/D epitaxial regions merge;
depositing a hardmask layer over the S/D epitaxial regions;
etching the hardmask layer to create openings that laterally trim the S/D epitaxial regions; and
depositing a dielectric material over the trimmed S/D epitaxial regions.

2. The method of claim 1, wherein the hardmask layer is a spin-on-carbon (SOC) layer.

3. The method of claim 1, wherein the dielectric material is a contact etch stop layer (CESL).

4. The method of claim 3, wherein the CESL encapsulates the trimmed S/D epitaxial regions.

5. The method of claim 3, wherein the CESL physically separates the trimmed S/D epitaxial regions from each other.

6. The method of claim 3, wherein the CESL assumes a shape of the trimmed S/D epitaxial regions.

7. The method of claim 1, wherein a sacrificial material is deposited before the depositing of the hardmask layer.

8. The method of claim 1, wherein a protective cap is formed over the gate structures to protect the gate structures from the etching of the hardmask layer.

9. The method of claim 8, wherein the protective cap includes silicon nitride (SiN).

10. A method, comprising:
forming source/drain (S/D) epitaxial regions over gate structures such that the S/D epitaxial regions merge;
depositing a hardmask layer over the S/D epitaxial regions;
etching the hardmask layer to create openings that laterally trim the S/D epitaxial regions; and
depositing dielectric within the openings to define dielectric walls between the trimmed the S/D epitaxial regions.

11. The method of claim 10, wherein the hardmask layer is a spin-on-carbon (SOC) layer.

12. The method of claim 10, wherein the dielectric walls extend above a top surface of the trimmed the S/D epitaxial regions.

13. The method of claim 10, wherein the dielectric walls directly contact at least a portion of side surfaces of the trimmed the S/D epitaxial regions.

14. The method of claim 10, wherein the dielectric walls are vertically offset from the gate structures.

15. A semiconductor structure, comprising:
trimmed source/drain (S/D) epitaxial regions disposed over gate structures; and
a dielectric material adjacent the trimmed S/D epitaxial regions.

16. The semiconductor structure of claim 15, wherein the dielectric material encapsulates the trimmed S/D epitaxial regions.

17. The semiconductor structure of claim 15, wherein the dielectric material assumes a shape of the trimmed S/D epitaxial regions.

18. The semiconductor structure of claim 15, wherein the dielectric material is configured to define dielectric walls between the trimmed S/D epitaxial regions.

19. The semiconductor structure of claim 18, wherein the dielectric walls extend above a top surface of the trimmed the S/D epitaxial regions.

20. The semiconductor structure of claim 18, wherein the dielectric walls directly contact at least a portion of side surfaces of the trimmed the S/D epitaxial regions.
